(19) United States
(12) Patent Application Publication
(10) Pub. No.: US 2012/0070577 A1
(43) Pub. Date: Mar. 22, 2012

(54) FILM-FORMING APPARATUS AND FILM-FORMING METHOD

(76) Inventors: Kaori DEURA, Kanagawa (JP); Shinya Higashi, Kanagawa (JP); Kunihiko Suzuki, Shizuoka (JP); Hideki Ito, Kanagawa (JP)

(21) Appl. No.: 13/231,265

(22) Filed: Sep. 13, 2011

(30) Foreign Application Priority Data
Sep. 22, 2010 (JP) 2010-212541

(51) Int. Cl. C23C 16/46; B05C 13/00; B05C 9/14

(52) U.S. Cl. 427/248.1; 118/58

(57) ABSTRACT

A film-forming apparatus and film-forming method is provided that includes a reflector system capable of adjusting the temperature distribution of a substrate. The essential role of a reflector is to reduce the output of a heater by reflecting radiation heat from the heater and to protect members provided below the heater from heat. When a silicon wafer is heated by a first heater and a second heater, the temperature of the silicon wafer becomes higher in the inner circumferential part of the wafer rather than in the outer circumferential part of the silicon wafer. When a ring-shaped reflector is used, radiation heat is reflected by the ring-shaped portion, but is not reflected by the inner circumferential part of the reflector. Therefore, the use of a ring-shaped reflector makes it possible to allow a wafer to have an even heating distribution.

### CROSS-REFERENCE TO THE RELATED APPLICATION

The entire disclosure of the Japanese Patent Application No. 2010-212541, filed on Sep. 22, 2010 including specifications, claims, drawings, and summary, on which the Convention priority of the present application is based, are incorporated herein in their entirety.

### FIELD OF THE INVENTION

The present invention relates to a film-forming apparatus and film-forming method.

### BACKGROUND

A GaN-based compound semiconductor (general formula: AlxGayIn1-x-yN) has a direct transition-type energy band structure, and is a wide band gap semiconductor with a band gap energy of 1.9 eV to 6.2 eV at room temperature. Such a GaN-based compound semiconductor can be widely used in light-emitting diodes and laser diodes that cover a wide range of emission wavelengths from the ultraviolet to the visible regions and light-receiving elements such as UV sensors.

An example of a conventional method for producing a light-receiving element is one in which a buffer layer is provided on a substrate with high flatness such as sapphire and a device layer including a light-receiving region is formed on the buffer layer. The reason why the buffer layer is provided is to reduce lattice mismatch between the lattice spacing of the crystal growth surface of the sapphire substrate and the lattice spacing of GaAlN of the light-receiving region to reduce threading dislocations that can be generated by lattice mismatch in the light-receiving region.

There is also a method in which, instead of a single buffer layer, two or more buffer layers are provided between a sapphire substrate and a device layer. For example, a multilayered nitride semiconductor substrate layer composed of a low temperature-deposited buffer layer made of AlN, a crystallization improving layer made of GaN, and a low temperature-deposited interlayer made of AlN is provided on a sapphire substrate, and a device layer is provided on the multilayered nitride semiconductor substrate layer. According to this method, it is possible to further reduce lattice mismatch between a substrate and a light-receiving region as compared to a case where a single buffer layer is provided.

However, when a device layer mainly made of GaAlN is formed on the above-described multilayered nitride semiconductor substrate layer to produce a light-receiving element according to the above method, light that is allowed to enter the light-receiving element from the substrate side is absorbed by the GaN layer whose band gap energy is lower than that of GaAlN. Therefore, incident light can enter the light-receiving element only from the upper side.

The crystallization improving layer constituting the above-described multilayered nitride semiconductor substrate layer may be made of, instead of GaN, GaAlN whose AlN compositional ratio is higher than that of GaAlN constituting the device layer or AlN, which makes it possible to solve the above problem.

Meanwhile, a group III-V nitride compound semiconductor such as GaAlN is produced by epitaxial growth of group III-V nitride semiconductor crystals on a sapphire substrate by organometallic vapor-phase epitaxy. Such an epitaxial growth technique is used in the process of producing a semiconductor device that requires a crystalline film having a relatively large thickness.

In order to produce thick epitaxial wafers in high yield, it is necessary to continuously bring fresh raw material gases into contact with the surface of a uniformly-heated wafer. To improve a film-forming rate, epitaxial growth is performed while a wafer is rotated at high speed (see, for example, Japanese Patent Application Laid-Open No. 5-152207).

Japanese Patent Application Laid-Open No. 5-152207 discloses a film-forming apparatus in which a wafer is rotated by rotating a shaft connected to a susceptor support into which a ring-shaped susceptor supporting the wafer is fitted. The film-forming apparatus includes a heater provided on the back surface side of the wafer, and further includes a heat transfer plate made of carbon and provided between the wafer and the heater.

In the film-forming apparatus disclosed in Japanese Patent Application Laid-Open No. 5-152207, a wafer is heated by the heat transfer plate heated by the heater. The susceptor has a counterbore provided on its inner circumferential side so that the outer periphery of the wafer can be positioned in the counterbore. That is, the outer periphery of the wafer is in contact with the susceptor, and therefore heat is likely to be dissipated through the outer periphery of the wafer. Further, the temperature of the heater is generally lower in the outer circumferential part than in the inner circumferential part of the heater.

In view of the above, a heater that mainly heats the outer circumferential part of a wafer is provided. However, in this case, a temperature difference is established between the outer circumferential part and the inner circumferential part of the wafer. Such a temperature difference causes the formation of an epitaxial film of non-uniform thickness. Therefore, there is a demand for a technique for heating a wafer so that the wafer can have a uniform temperature distribution.

The present invention has been made in view of the above circumstances. It is an object of the present invention to provide a film-forming apparatus capable of adjustment of the temperature distribution of a substrate.

It is also an object of the present invention to provide a film-forming method capable of forming a film having a desired thickness by uniformly heating a substrate.

Other challenges and advantages of the present invention are apparent from the following description.

### SUMMARY OF THE INVENTION

In one aspect of the present invention, a film-forming apparatus comprising: a film-forming chamber, a susceptor provided in the film-forming chamber to place a substrate thereon, a rotating unit that rotates the susceptor, a heater located below the susceptor, and a reflector located below the heater, wherein the reflector is a combination of a ring-shaped reflector and a disk-shaped reflector.

In another aspect of the present invention, a film-forming apparatus comprising: a film-forming chamber, a susceptor provided in the film-forming chamber to place a substrate thereon, a rotating unit that rotates the susceptor, a heater located below the susceptor; and a heat insulator located below the heater, wherein the heat insulator has an outer circumferential part and an inner circumferential part thinner than the outer circumferential part.

In another aspect of the present invention, a film-forming method comprising: forming a predetermined film on a substrate in a film-forming chamber while the substrate is heated by a heater provided below a substrate, wherein a combination of a ring-shaped reflector and a disk-shaped reflector is provided below the heater.

### BRIEF DESCRIPTION OF DRAWINGS

FIG. 1 is a schematic sectional view of a film-forming apparatus according to a first embodiment of the present invention.

FIG. 2 is a plan view of a reflector assembly.

FIG. 3 is a graph showing a temperature comparison between a semiconductor substrate with a reflector assembly and without a reflector assembly.

FIG. 4a is another example of a reflector assembly, in which the positional relation between the first reflectors and the second reflectors is reversed.

FIG. 4b is another example of a reflector assembly, in which the first reflectors and the second reflectors are alternately arranged.

FIG. 4c is another example of a reflector assembly, in which the first reflectors differing in diameter of their inner circumferential parts are arranged, and the second reflector is arranged under the first reflectors.

FIG. 5 shows another example of a reflector that can be used in the first embodiment.

FIG. 6 is a sectional view of a heat insulator that can be used in the first embodiment.

FIG. 7 is a schematic sectional view of a film-forming apparatus according to the second embodiment.

FIG. 8 shows the inner circumferential and outer circumferential locations of a substrate.

### DETAILED DESCRIPTION OF EMBODIMENTS

According to the present embodiments, it is possible to provide a film-forming apparatus capable of adjustment of the temperature distribution of a substrate. According to the present embodiments, it is also possible to provide a film-forming method capable of forming a film having a desired thickness by uniformly heating a substrate.

### Embodiment 1

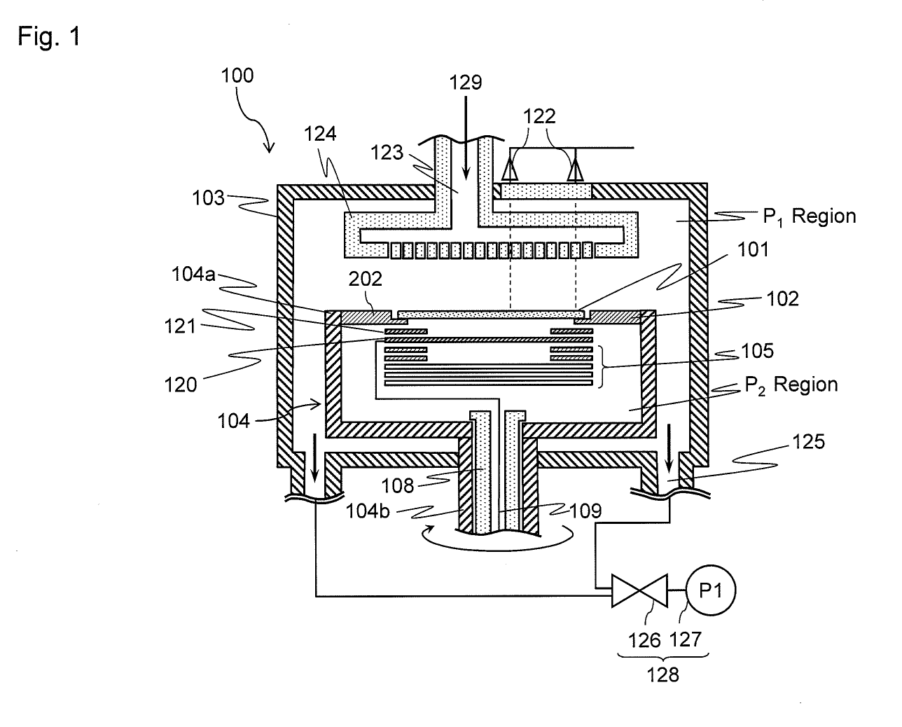

FIG. 1 is a schematic sectional view of a film-forming apparatus 100 according to a first embodiment of the present invention.

According to the first embodiment, a silicon wafer 101 is used as a substrate. However, the substrate is not limited thereto, and in some cases, a wafer made of another material may be used.

The film-forming apparatus 100 includes a chamber 103 as a film-forming chamber.

In an upper part of the chamber 103, a gas supply portion 123 that supplies a raw material gas 129 for growing a crystalline film on the surface of the heated silicon wafer 101 is provided. Further, the gas supply portion 123 is connected to a shower plate 124 having a plurality of discharge holes for discharging the raw material gas 129. The shower plate 124 is provided so as to be opposite to the surface of the silicon wafer 101 so that the raw material gas 129 is supplied to the surface of the silicon wafer 101.

In a lower part of the chamber 103, two or more gas discharge portions 125 for discharging the raw material gas 129 after reaction are provided. The gas discharge portions 125 are connected to a gas discharge mechanism 128 constituted from a regulating valve 126 and a vacuum pump 127. The gas discharge mechanism 128 is controlled by a control mechanism (not shown) so that the pressure in the chamber 103 is adjusted to a predetermined pressure.

Inside the chamber 103, a susceptor 102 is provided at the upper end of a rotating unit 104. The susceptor 102 is exposed to high temperature, and is therefore made of, as one example, high-purity SiC. The silicon wafer 101 transported into the chamber 103 is placed on the susceptor 102.

The rotating unit 104 includes a cylindrical part 104a and a rotating shaft 104b. The rotating shaft 104b extends to the outside of the chamber 103, and is connected to a rotating mechanism (not shown). The susceptor 102 can be rotated by rotating the cylindrical part 104a at a predetermined number of revolutions per minute. This makes it possible to rotate the silicon wafer 101 supported by the susceptor 102. The cylindrical part 104a is preferably rotated about an axis passing through the center of the silicon wafer 101 and intersecting with the silicon wafer 101 at a right angle.

As shown in FIG. 1, the cylindrical part 104a has an opening at its upper end. However, the upper opening of the cylindrical part 104a is covered with the susceptor 102 and the silicon wafer 101 placed on the susceptor 102 so that the cylindrical part 104a has a hollow region (hereinafter, referred to as a “P2 region”) inside. When the region inside the chamber 103 is defined as a P₁ region, the P₂ region is substantially separated from the P₁ region by the susceptor 102 and the silicon wafer 101.

In the P₂ region, a heating unit including a first heater 120 and a second heater 121 is provided. The first heater 120 is provided at a position corresponding to the inner circumferential part of the silicon wafer 101. The first heater 120 can have, for example, a disk shape. On the other hand, the second heater 120 is provided at a position corresponding to the outer circumferential part of the silicon wafer 101 so as to be interposed between the silicon wafer 101 and the first heater 120. The outer-heater 121 can have, for example, an annular shape. An electric current is supplied to these heaters through wiring 109 running through the inside of a substantially-cylindrical quartz shaft 108 provided inside the rotating shaft 104b to heat the silicon wafer 101 from the back surface side of the silicon wafer 101. However, the heating unit used in the first embodiment may have a structure in which only one heater is provided.

The surface temperature of the silicon wafer 101, changed as a result of heating, is measured by a radiation thermometer 122 provided in the upper part of the chamber 103. By using the shower plate 124 made of transparent quartz, the surface temperature of the silicon wafer 101 can be measured by the radiation thermometer 122 without interference from the shower plate 124. Temperature data measured by the radiation thermometer 122 is transferred to a control mechanism (not shown) and fed back to control the output of the first heater 120 and the output of the second heater 120. This makes it possible to heat the silicon wafer 101 so that the silicon wafer 101 can reach a desired temperature.

In the film-forming apparatus 100 according to the first embodiment, a reflector assembly 105 is provided under the first heater 120. The reflector assembly 105 is constituted of two or more reflectors, and the reflectors interact with one another to exert an influence on the temperature distribution of the silicon wafer 101.

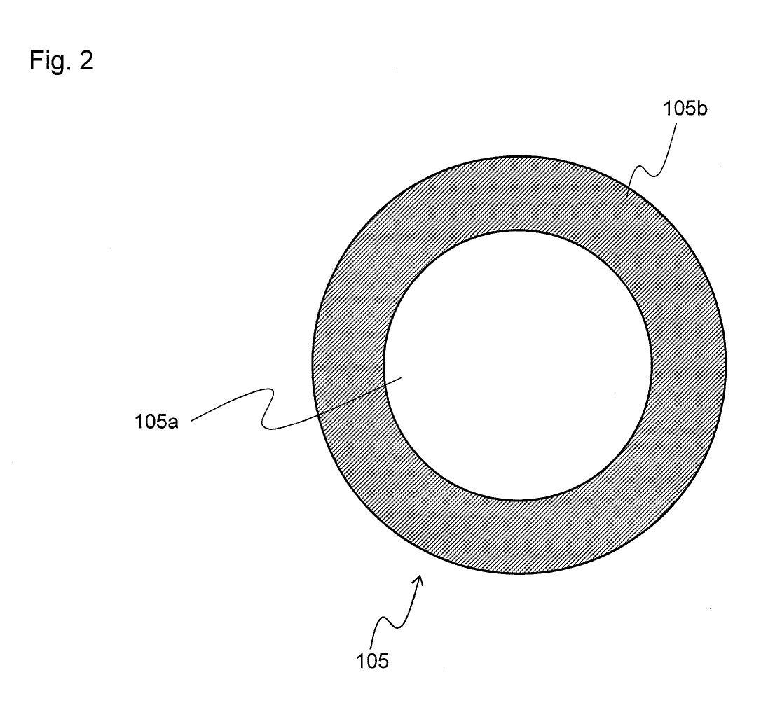

FIG. 2 is a plan view of the reflector assembly 105. As shown in FIG. 2, the reflector assembly 105 is constituted from two or more ring-shaped first reflectors 105a and two or more disk-shaped second reflectors 105b. In the reflector assembly 105 shown in FIG. 1 by way of example, the first reflectors 105a are provided under the first heater 120 and the second reflectors 105b are further provided under the first reflectors 105a. It is to be noted that in this specification, the word “disk-shaped” refers to any circular shape not having a hole at least in its center region.

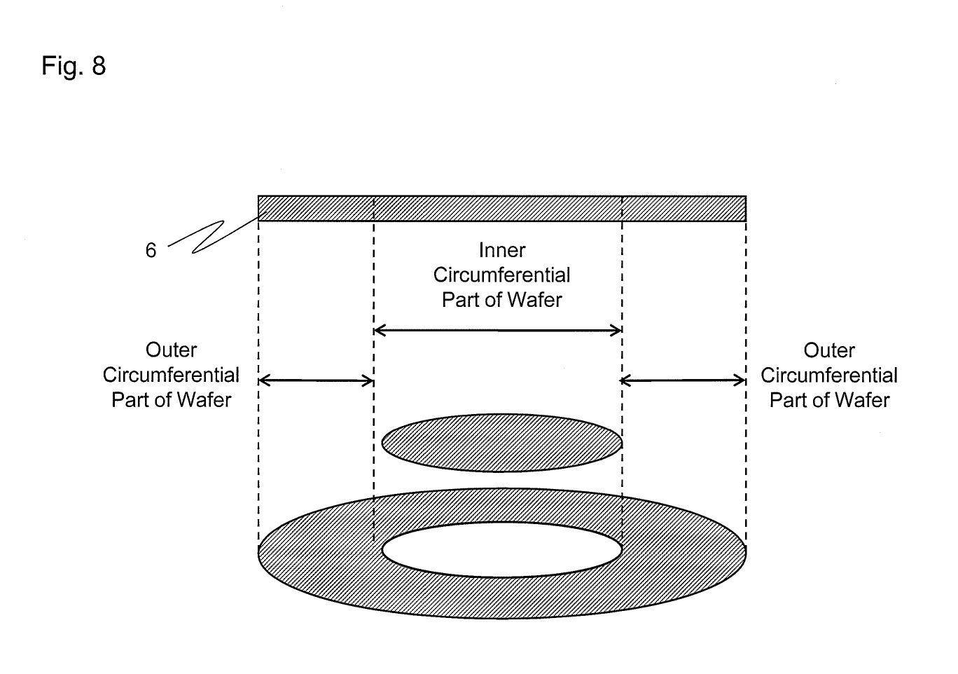

FIG. 8 shows the inner circumferential and outer circumferential locations of a substrate.

When the silicon wafer 101 is heated by the first heater 120 and the second heater 120, the temperature of the silicon wafer 101 becomes higher in the inner circumferential part than in the outer circumferential part of the silicon wafer 101. In this case, the temperature distribution of the silicon wafer 101 can be made uniform by increasing heat dissipation from the inner circumferential part of the reflector so that the temperature of the inner circumferential part of the silicon wafer 101 is decreased.

The essential role of a reflector is to reduce the output of a heater by reflecting radiation heat from the heater and to protect members provided below the heater from heat from the heater. When a ring-shaped reflector is used, radiation heat is reflected by the ring-shaped portion, but is not reflected by the inner circumferential part of the reflector. Therefore, the use of a ring-shaped reflector makes it possible to allow a wafer to have an even heating distribution.

For this reason, the reflector assembly 105 constituted from the ring-shaped first reflectors 105a and the disk-shaped second reflectors 105b as shown in FIG. 2 is provided so that the ring-shaped portion of each of the first reflectors 105a is located at a position corresponding to the outer circumferential part of the silicon wafer 101. This makes it possible to heat the outer circumferential part of the silicon wafer 101 while suppressing heating of the inner circumferential part of the silicon wafer 101. As a result, the temperature distribution of the silicon wafer 101 can be changed so that the temperature of the inner circumferential part of the silicon wafer 101 is decreased. It is to be noted that in this case, the disk-shaped second reflectors 105b are also provided, and therefore members provided below the heaters can be protected from heat from the heaters.

As described above, the use of a ring-shaped reflector makes it possible to allow a wafer to have an even heating distribution. However, in order to allow a wafer to have a desired heating distribution, a ring-shaped reflector is preferably used in combination with a disk-shaped reflector, and more preferably, two or more ring-shaped reflectors and two or more disk-shaped reflectors are used to adjust a heating distribution. That is, as shown in FIG. 1, the reflector assembly 105 obtained by combining the first reflectors 105a and the second reflectors 105b is used. The temperature distribution of the silicon wafer 101 can be changed by changing the number of the first reflectors 105a and/or the number of the second reflectors 150b or by changing the diameter of the inner circumferential part of the first reflector 105a. That is, the temperature of the inner circumferential part of the silicon wafer 101 can be made lower than that of the outer circumferential part of the silicon wafer 101 or the temperature of the inner circumferential part of the silicon wafer 101 can be equal to that of the outer circumferential part of the silicon wafer 101.

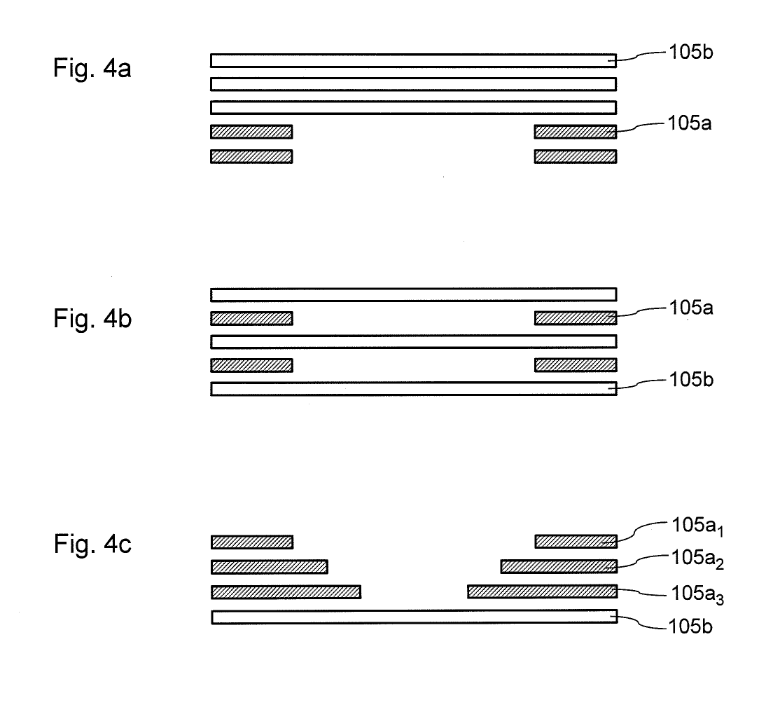

FIGS. 4a to 4c show modifications of a reflector assembly used in the first embodiment.

A reflector assembly shown in FIG. 4a is different from the reflector assembly 105 shown in FIG. 1 in that the positional relation between the first reflectors 105a and the second reflectors 105b is reversed. That is, the reflector assembly shown in FIG. 4a has a structure in which the second reflectors 105b are provided under the first heater 120 and the first reflectors 105a are further provided under the second reflectors 105b. The reflector assembly having such a structure also has the same effect as the reflector assembly shown in FIG. 1.

A reflector assembly shown in FIG. 4b has a structure in which the first reflectors 105a and the second reflectors 105b are alternately arranged. The reflector assembly having such a structure also has the same effect as the reflector assembly shown in FIG. 1.

A reflector assembly shown in FIG. 4c has a structure in which first reflectors 105a₁ to 105a₃ different in diameter of their inner circumferential parts are arranged in descending order of diameter of their inner circumferential parts from top to bottom, and the second reflector 105b is arranged under the first reflector 105a₃. The reflector assembly having such a structure also has the same effect as the reflector assembly shown in FIG. 1. The first reflectors 105a₁ to 105a₃ slightly differ from one another in diameter of their inner circumferential parts, and therefore when the reflector assembly shown in FIG. 4c is used, more delicate temperature control can be achieved than when the other reflector assemblies are used.

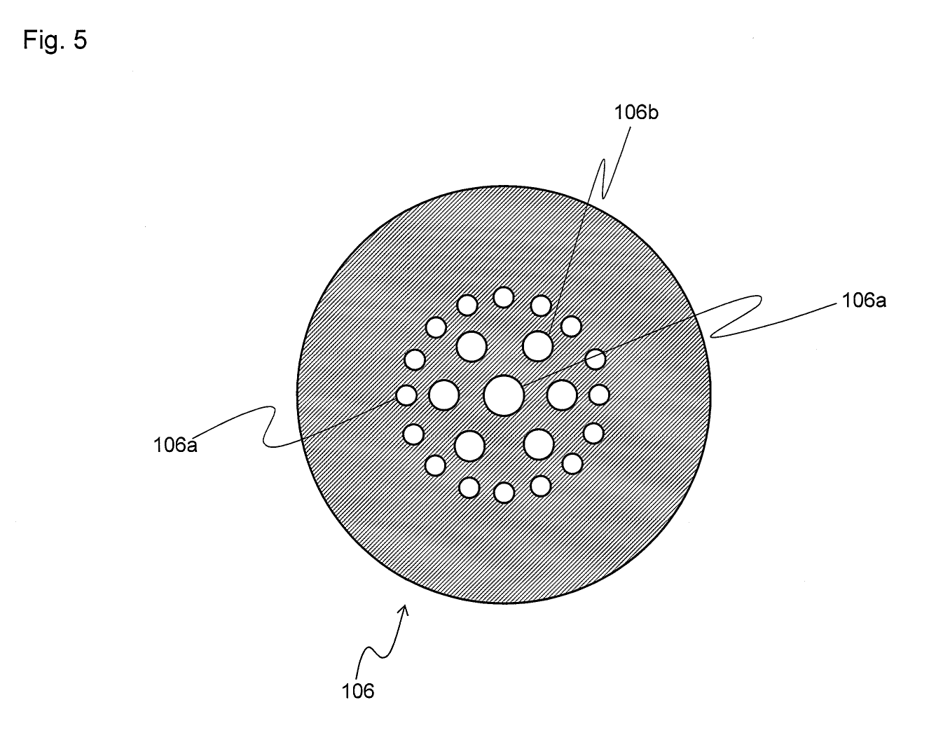

FIG. 5 shows another reflector that can be used in the first embodiment. A reflector 106 shown in FIG. 5 is a disk-shaped reflector having holes 106a, 106b, and 106c different in diameter. The number of reflectors 106 provided under the first heater 120 may be one, two, or more. When two or more reflectors 106 are provided, they constitute a reflector assembly as in the case of the reflector assembly shown in FIG. 1 or 4. The diameters, numbers, and positions of the holes can be appropriately changed. In order to improve heat dissipation from the inner circumferential part of the silicon wafer 101, the holes are arranged mainly in the inner circumferential part of the reflector 106 as shown in FIG. 5. However, when it is necessary to improve heat dissipation from the outer circumferential part of the silicon wafer 101, the holes are arranged mainly in the outer circumferential part of the reflector 106.

All the reflectors used in the first embodiment are made of a highly heat-resistant material such as Si. However, the reflectors arranged near the heaters, for example, the first reflectors 105a shown in FIG. 2 or the second reflectors 105b shown in FIG. 4a, are preferably made of a high heat-resistant material such as SiC or carbon coated with SiC.

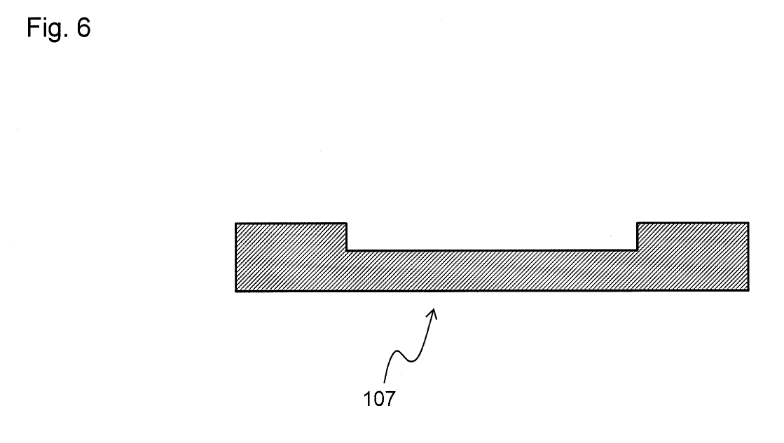

According to the first embodiment, a heat insulator may be used instead of the reflector(s). FIG. 6 is a sectional view of a heat insulator that can be used in the first embodiment. As shown in FIG. 6, a heat insulator 107 has an outer circumferential part and an inner circumferential part thinner than the outer circumferential part so that heat dissipation from the inner circumferential part of the silicon wafer 101 can be improved. The heat insulator can be made of, for example, porous carbon or carbon fibers. A specific example of the material of the heat insulator includes KRECA (trade name) manufactured by KUREHA Corporation.

Further, the heat insulator 107 mentioned above may also be used in combination with the afore-mentioned reflectors.

Hereinbelow, one example of a film-forming method according to the first embodiment will be described with reference to FIGS. 1 and 2. It is to be noted that, instead of the reflector assembly 105 shown in FIG. 2, the reflector assembly shown in FIG. 4a, 4b, or 4c, the reflector (assembly) shown in FIG. 5, or the heat insulator 107 shown in FIG. 6 may be used.

First, the silicon wafer 101 is placed on the susceptor 102.

Then, the silicon wafer 101 is rotated at about 50 rpm by rotating the rotating unit 104 while hydrogen gas is allowed to flow under ordinary pressure or an appropriate reduced pressure.

Then, the silicon wafer 101 is heated to a temperature between 1100 to 1200° C. by the first heater 120 and the second heater 120. For example, the silicon water 101 is gradually heated to approximately 1150° C. at which point a film is formed.

According to the first embodiment, the reflector assembly 105 is provided under the first heater 120. The reflector assembly 105 is constituted from the ring-shaped first reflectors 105a and the disk-shaped second reflectors 105b. The first reflectors 105a heat the outer circumferential part of the silicon wafer 101 while suppressing the heating of the inner circumferential part of the silicon wafer 101. This makes it possible to heat the silicon wafer 101 while decreasing the temperature of the inner circumferential part of the silicon wafer 101 so that the silicon wafer 101 can have a desired temperature distribution.

After it is confirmed that the temperature of the silicon wafer 101 measured by the radiation thermometer 122 has reached approximately 1150° C., the number of revolutions of the silicon wafer 101 is gradually increased. Then, the raw material gas 129 is supplied from the gas supply portion 123 into the chamber 103 through the shower plate 124. According to the first embodiment, trichrolosilane can be used as the raw material gas 129, and a mixture gas of trichlorosilane and hydrogen gas is introduced from the gas supply portion 123 into the chamber 103.

The raw material gas 129 introduced into the chamber 103 flows downward toward the silicon wafer 101. The fresh raw material gas 129 is continuously supplied from the gas supply portion 123 to the silicon wafer 101 through the shower plate 124 while the temperature of the silicon wafer 101 is kept at approximately 1150° C. and the susceptor 102 is rotated at a speed of approximately 900 rpm or more. This makes it possible to efficiently form an epitaxial film at a high film-forming rate.

As described above, a silicon epitaxial layer having a uniform thickness can be grown on the silicon wafer 101 by introducing raw material gas 129 while the susceptor 102 is rotated. For example, in the case of a power semiconductor device, a thick film having a thickness of 10 μm or more can be grown, in most cases, about 10 μm to 100 μm is formed on a 200 mm silicon wafer. In order to form a thick film, the number of revolutions of a substrate during film formation is preferably increased. As described above, the number of revolutions of a substrate is preferably increased to approximately 900 rpm.

It is to be noted that the silicon wafer 101 can be transported into and out of the chamber 103 by any well-known method.

### Embodiment 2

A second embodiment of the present invention will be described with reference to a case where a group III-V nitride compound semiconductor substrate is formed. An example of such a semiconductor substrate includes one obtained by stacking a first AlN buffer layer, an AlN semiconductor layer, and a second AlN buffer layer on a sapphire substrate.

The first AlN buffer layer is formed so as to have a thickness of 20 nm by, for example, a MOCVD (Metalorganic Chemical Vapor Deposition) method using raw material gases such as trimethylaluminum (Al source) and ammonia (N source) at a temperature in the range of 300 to 800° C. (for e.g., at a temperature of 500° C.).

The AlN semiconductor layer is formed so as to have a thickness of 500 nm or more (e.g., 1 μm) by a MOCVD method using the above-mentioned raw material gases at a temperature of about 1280° C. or higher (e.g., 1300° C.). At this time, An is epitaxially grown as a single crystal, and therefore the film-forming apparatus according to the present embodiment is preferably used.

The second AlN buffer layer is formed under the same conditions as described above with reference to the first AlN buffer layer. That is, the second An buffer layer is formed so as to have a thickness of 20 nm on the AlN semiconductor layer.

It is to be noted that when any one of the first AlN layer, the An semiconductor layer, and the second AlN buffer layer is formed as a GaAlN layer, trimethylgallium (Ga source) is used as a raw material gas in addition to the above-mentioned raw material gases.

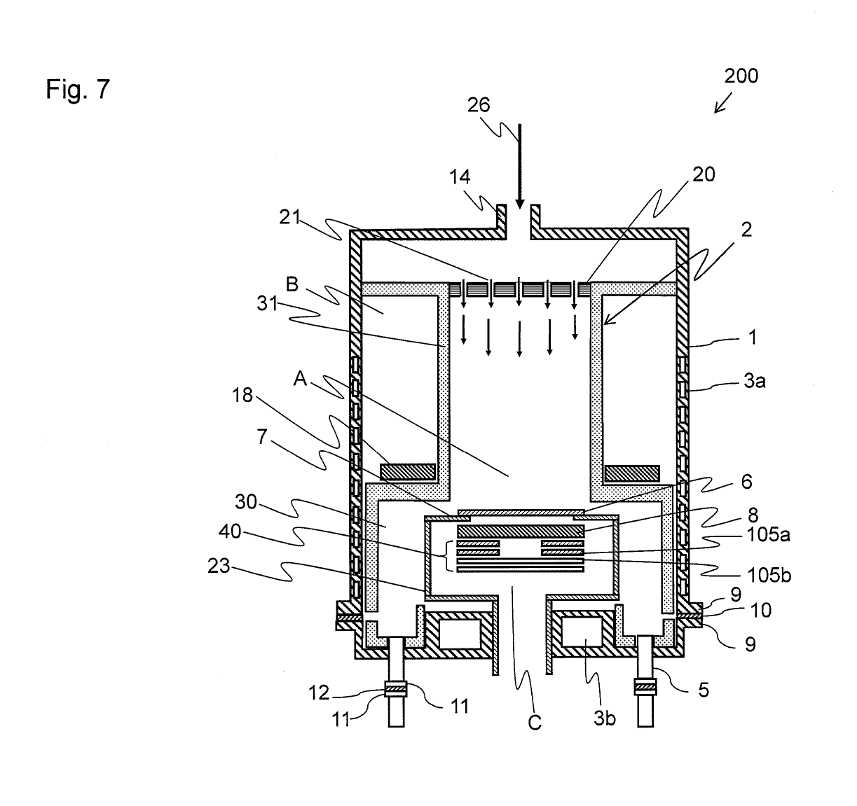

FIG. 7 is a schematic sectional view of a film-forming apparatus 200 according to the second embodiment. The film-forming apparatus 200 shown in FIG. 7 can be used for forming an AlN semiconductor layer.

The film-forming apparatus 200 includes a chamber 1 as a film-forming chamber, a hollow cylindrical liner 2 provided in the chamber 1, channels 3a and 3b for supplying cooling water for cooling the chamber 1, a reaction gas supply portion 14 for introducing a reaction gas 26 into the chamber 1, a gas discharge portion 5 through which the reaction gas 26 after reaction is discharged to the outside of the chamber 1, a susceptor 7 on which a semiconductor substrate 6 is to be placed, a lower heater 8 that is supported by a support unit (not shown) and heats the semiconductor substrate 6, an upper heater 18 that is supported by a support unit (not shown) and heats the semiconductor substrate 6, a flange portion 9 through which upper and lower parts of the chamber 1 are connected to each other, a gasket 10 that seals the flange portion 9, a flange portion 11 through which the gas discharge portion 5 and a pipe are connected to each other, and a gasket 12 that seals the flange portion 11.

The liner 2 is made of a heat-resistant material. For example, a member formed by coating carbon with SiC can be used. The liner 2 has a head part 31 having an opening, and a shower plate 20 is fitted into the opening. The shower plate 20 functions as a gas straightening vane for supplying the reaction gas 26 uniformly to the surface of the semiconductor substrate 6. The shower plate 20 has a plurality of through holes 21 for supplying the reaction gas 26.

It is to be noted that the reason why the liner 2 is provided is that the wall of a chamber generally used in a film-forming apparatus is made of stainless steel. That is, the film-forming apparatus 200 uses the liner 2 to prevent the wall made of stainless steel from being exposed to a gas-phase reaction system. The liner 2 has the effect of preventing the deposition of particles on the wall of the chamber 1, contamination of the wall of the chamber 1 with metals, or erosion of the wall of the chamber 1 by the reaction gas 26 during formation of a crystalline film.

The liner 2 has a hollow cylindrical form, and includes a body part 30, in which the susceptor 7 is provided, and the head part 31 whose inner diameter is smaller than that of the body part 30.

On the susceptor 7, the semiconductor substrate 6 is to be placed. The semiconductor substrate 6 can be, as one example, a sapphire substrate having an AlN buffer layer formed thereon.

The susceptor 7 is attached to the upper end of a hollow cylindrical rotating cylinder 23. The rotating cylinder 23 is connected to a rotating mechanism (not shown) via a rotating shaft (not shown) extending from the bottom to the inside of the chamber 1. That is, the susceptor 7 is rotatably provided above the lower heater 8 and inside the body part 30 of the liner 2. Therefore, the semiconductor substrate 6 placed on the susceptor 7 is rotated at high speed by rotating the susceptor 7 during a gas-phase growth reaction.

In order to form an AlN semiconductor layer on the semiconductor substrate 6, a mixture gas obtained by mixing trimethylaluminum (Al source) and ammonia (N source) as the source gases, and hydrogen (H₂) gas as a carrier gas, is used as the reaction gas 26. This mixture gas is introduced from the reaction gas supply portion 14 of the film-forming apparatus 200. More specifically, the mixture gas is introduced into the liner 2, that is, into a first space (space A) extending from the reaction gas supply portion 14 to an area around the semiconductor substrate 6.

As described above, the shower plate 20 is fitted into the upper opening of the head part 31 of the liner 2. The shower plate 20 functions as a gas straightening vane for uniformly supplying the reaction gas 26 to the surface of the semiconductor substrate 6 placed on the susceptor 7 provided inside the body part 30.

The inner diameter of the head part 31 of the liner 2 is determined so as to correspond to the size of the semiconductor substrate 6 in consideration of the arrangement of the through holes 21 of the shower plate 20. This makes it possible to reduce wasted space where the reaction gas 26 that has passed through the through holes of the shower plate 20 diffuses. That is, the film-forming apparatus 200 is configured so that the reaction gas 26 supplied through the shower plate 20 can be efficiently focused on the surface of the semiconductor substrate 6 without wasting the reaction gas 26. Further, the film-forming apparatus 200 is configured so that the gap between the periphery of the semiconductor substrate 6 and the liner 2 can be minimized to allow the reaction gas to flow more uniformly on the surface of the semiconductor substrate 6.

The use of the liner 2 having such a structure as described above makes it possible to allow a gas-phase growth reaction to efficiently proceed on the surface of the semiconductor substrate 6. That is, the reaction gas 26 supplied to the reaction gas supply portion 14 is straightened in the space A when passing through the through holes 21 of the shower plate 20, and flows downward substantially vertically toward the semiconductor substrate 6 placed under the shower plate 20. That is, the reaction gas 26 forms a so-called vertical flow in a region extending from the shower plate 20 provided in the space A to the surface of the semiconductor substrate 6. The reaction gas 26 is attracted by the rapidly-rotating semiconductor substrate 6, the rotation of the semiconductor substrate 6 acts as an attraction effect by creating a vortex flow of the reaction gas 26 as it reaches the semiconductor substrate 6. The reaction gas 26 then comes into contact with the surface of the semiconductor substrate 6, and flows without turbulence as a substantially laminar flow in a horizontal direction along the upper surface of the semiconductor substrate 6. As described above, the reaction gas 26 is in a straightened state on the surface of the semiconductor substrate 6, and therefore an epitaxial film having high thickness uniformity and high quality can be formed.

The reaction gas 26 supplied to the surface of the semiconductor substrate 6 in such a manner as described above causes a reaction on the surface of the semiconductor substrate 6. As a result, an AlN epitaxial film is formed on the surface of the semiconductor substrate 6. The reaction gas 26 other than that used for a gas-phase growth reaction is turned into a denatured production gas and discharged through the gas discharge portion 5 provided in the lower part of the chamber 1.

In the film-forming apparatus 200 shown in FIG. 7, the flange portion 9 of the chamber 1 is sealed with the gasket 10 and the flange portion 11 of the gas discharge portion 5 is sealed with the gasket 12. The gaskets 10 and 12 are preferably made of fluorine rubber, but their upper temperature limits are about 300° C. According to the present embodiment, the channels 3a and 3b of cooling water for cooling the chamber 1 are provided to prevent the gaskets 10 and 12 from being thermally degraded.

The epitaxial growth of AlN is performed at a temperature of about 1280° C. or higher (e.g., 1300° C.). Therefore, the film-forming apparatus 200 shown in FIG. 7 includes the upper heater 18 and the lower heater 8 as means for heating the semiconductor substrate 6 placed inside the liner 2. In this case, minor adjustment to the temperature of the semiconductor substrate 6 is performed by the lower heater 8.

The upper heater 18 is a resistive heater formed by coating the surface of a carbon base material with a SiC material, and is provided in a second space (space B) created between the liner 2 and the inner wall of the chamber 1. From the viewpoint of efficiently heating the semiconductor substrate 6, the upper heater 18 is provided near the semiconductor substrate 6, more specifically, near a junction between the body part 30 and the head part 31 of the liner 2.

Similarly to the upper heater 18, the lower heater 8 is also a resistive heater formed by coating the surface of a carbon base material with a SiC material, and is provided in a third space (space C) under the susceptor 7, on which the semiconductor substrate 6 is to be placed, and inside the rotating cylinder 23. It is to be noted that as in the case of the first embodiment, the lower heater 8 may be the only heater provided.

When the upper heater 18 and the lower heater 8 are provided, the inner circumferential part is at a higher temperature than the outer circumferential part of the semiconductor substrate 6. This is a result of the inner circumferential part of the semiconductor substrate 6 receiving more heat radiation than the outer circumferential part.

That is, a larger amount of heat is exchanged by radiation between the upper heater 18 and the inner circumferential part of the semiconductor substrate 6, and therefore the temperature of the inner circumferential part of the semiconductor substrate 6 becomes higher than that of the outer circumferential part of the semiconductor substrate 6. In this case, it is difficult to make the temperature of the surface of the semiconductor substrate 6 uniform by temperature adjustment by the lower heater 8.

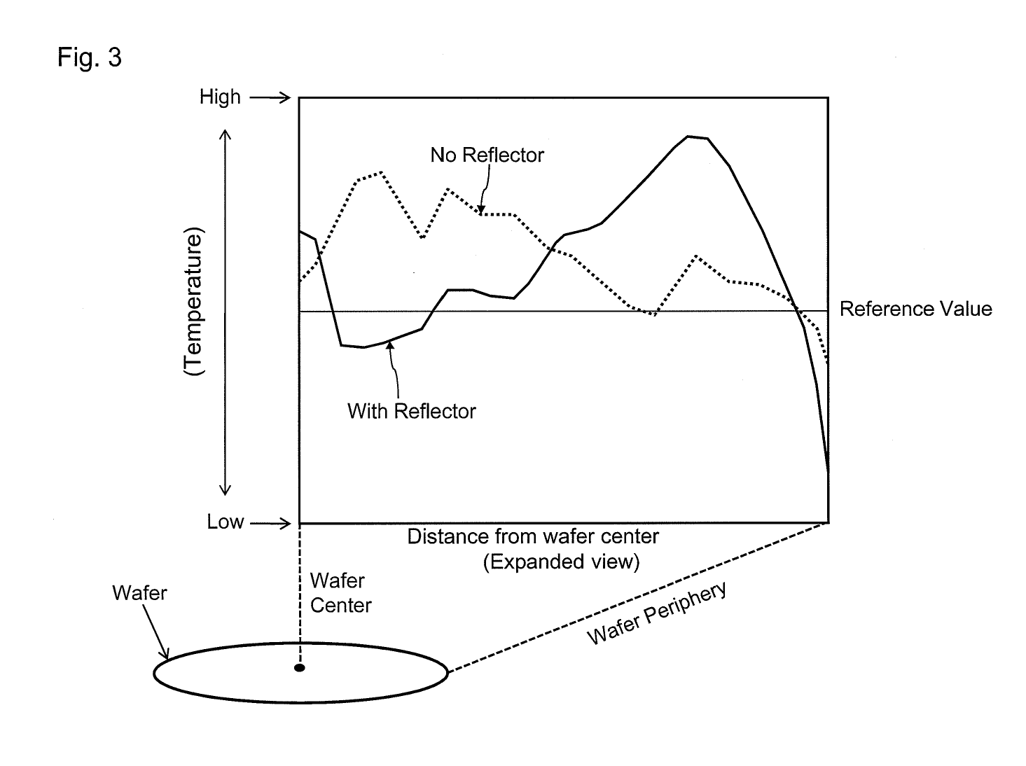

FIG. 3 is a graph showing an example of comparison of the temperature distribution of the semiconductor substrate 6 between when the reflector assembly 40 is provided in the film-forming apparatus 200 and when the reflector assembly 40 is not provided in the film-forming apparatus 200. In FIG. 3, the dotted line (1) represents the temperature distribution of the semiconductor substrate 6 when the reflector assembly 40 is not provided and the solid line (2) represents the temperature distribution of the semiconductor substrate 6 when the reflector assembly 40 is provided. It is to be noted that the horizontal axis in FIG. 3 represents a distance from the center of the semiconductor substrate 6 along a line connecting the center of the semiconductor substrate 6 with a point in the outer circumferential part of the semiconductor substrate 6, and the vertical axis in FIG. 3 represents the temperature of the surface of the semiconductor substrate 6.

As can be seen from the dotted line (1) in FIG. 3, the temperature of the semiconductor substrate 6 is higher in its inner circumferential part than in its outer circumferential part. That is, when the semiconductor substrate 6 is heated by the upper heater 18 and the lower heater 8, the temperature of the semiconductor substrate 6 becomes higher in its inner circumferential part than in its outer circumferential part. In this case, the temperature distribution of the semiconductor substrate 6 can be made uniform by decreasing the temperature of the inner circumferential part of the semiconductor substrate 6 by improving heat dissipation from the inner circumferential part of the semiconductor substrate 6.

Therefore, the film-forming apparatus 200 according to the second embodiment includes a reflector assembly 40 provided under the lower heater 8. The reflector assembly is constituted from two or more reflectors, and these reflectors interact with one another to exert an influence on the temperature distribution of the semiconductor substrate 6.

As the reflector assembly 40, the same one as used in the first embodiment can be used. For example, as shown in FIG. 2, the reflector assembly 40 can be constituted from the ring-shaped first reflectors 105a and the disk-shaped second reflectors 105b. In this case, as shown in FIG. 7, the first reflectors 105a can be provided under the lower heater 8 and the second reflectors 105b can be further provided under the first reflectors 105a.

As shown in FIG. 4a, the positional relation between the first reflectors 105a and the second reflectors 105b of the reflector assembly 40 may be the reverse of that shown in FIG. 7. Alternatively, as shown in FIG. 4b, the first reflectors 105a and the second reflectors 105b may be alternately arranged.

According to the second embodiment, as shown in FIG. 4c, the reflector assembly 40 may have a structure in which the first reflectors 105a₁ to 105a₃ different in diameter of their inner circumferential parts are arranged in descending order of diameter of their inner circumferential parts from the top and the second reflector 105b is arranged undermost.

The reflector assembly 40 may be constituted from the one or two or more disk-shaped reflectors shown in FIG. 5 having the holes 106a, 106b, and 106c different in diameter. In this case, the reflector assembly 40 is provided under the lower heater 8.

Further, the reflector assembly 40 may be constituted from a disk-shaped reflector having holes as shown in FIG. 5 and a ring-shaped reflector. In this case, the reflector assembly 40 is provided under the lower heater 8.

By providing the reflector assembly 40 in the film-forming apparatus 200, it is possible to change the temperature distribution of the semiconductor substrate 6. More specifically, when a ring-shaped reflector is used, radiation heat is reflected by the ring-shaped portion of the reflector, but is not reflected by the inner circumferential part of the reflector. That is, the use of a ring-shaped reflector makes it possible to allow a semiconductor substrate to have a even heating distribution.

For example, as shown in FIG. 7, the reflector assembly 40 constituted from the ring-shaped first reflectors 105a and the disk-shaped second reflectors 105b is provided so that the ring-shaped portion of each of the first reflectors 105a is arranged at a position corresponding to the outer circumferential part of the semiconductor substrate 6. This makes it possible to heat the outer circumferential part of the semiconductor substrate 6 while suppressing heating of the inner circumferential part of the semiconductor substrate 6. In other words, heat dissipation from the inner circumferential part of the semiconductor substrate 6 is improved. Therefore, it is possible to change the temperature distribution of the surface of the semiconductor substrate 6 so that the temperature of the inner circumferential part of the semiconductor substrate 6 is decreased. Further, the semiconductor substrate 6 is allowed to have a desired temperature distribution by changing the number of the ring-shaped reflectors and/or the number of the disk-shaped reflectors or by changing the diameter of the inner circumferential parts of the ring-shaped reflectors. That is, the temperature of the inner circumferential part of the semiconductor substrate 6 can be made lower than that of the outer circumferential part of the semiconductor substrate 6 as represented by the solid line (2) in FIG. 3 or the temperature of the inner circumferential part of the semiconductor substrate 6 can be made equal to that of the outer circumferential part of the semiconductor substrate 6.

The output of the lower heater 8 may be increased by improving heat dissipation from the inner circumferential part of the semiconductor substrate 6 to fulfill the function of adjusting the temperature of the semiconductor substrate 6. When the output of the lower heater 8 is increased, the output of the upper heater 18 is significantly decreased, and therefore the total output of the upper heater 18 and the lower heater 8 can be made lower as compared to a case where the reflector assembly 40 is not provided.

It is to be noted that, instead of the reflector assembly 40, a heat insulator having an outer circumferential part and inner circumferential part thinner than the outer circumferential part such as the heat insulator 107 shown in FIG. 6 may be used. Also in this case, the same effect as described above can be obtained.

Hereinbelow, one example of a film-forming method according to the second embodiment will be described with reference to FIG. 7. It is to be noted that, as described above, instead of the reflector assembly 40 shown in FIG. 7, the same reflector assembly as shown in FIG. 4a, 4b, or 4c, the same reflector (assembly) as described above with reference to FIG. 5, or the heat insulator 107 shown in FIG. 6 may be used.

First, the semiconductor substrate 6 is transported into the chamber 1 and placed on the susceptor 7. Then, the semiconductor substrate 6 placed on the susceptor 7 is rotated at about 50 rpm by rotating the rotating cylinder 23 and the susceptor 7.

The upper heater 18 and the lower heater 8 are activated by supplying an electric current to heat the semiconductor substrate 6 by heat emitted from the upper heater 18 and the lower heater 8. The semiconductor substrate 6 is gradually heated until the temperature of the semiconductor substrate 6 reaches a temperature of about 1280° C. or higher (e.g., 1300° C.) at which a film is formed. At this time, the temperature of the upper heater and the lower heater 8 becomes higher than 1300° C. Therefore, cooling water is allowed to flow through the channels 3a and 3b provided in the wall of the chamber 1 to prevent an excessive increase in the temperature of the chamber 1.

According to the second embodiment, the reflector assembly 40 is provided under the lower heater 8. The reflector assembly 40 is constituted from the ring-shaped first reflectors 105a and the disk-shaped second reflectors 105b. The first reflectors 105a heat the outer circumferential part of the semiconductor substrate 6 but suppress heating of the inner circumferential part of the semiconductor substrate 6. This makes it possible to heat the semiconductor substrate 6 while decreasing the temperature of the inner circumferential part of the semiconductor substrate 6 so that the semiconductor substrate 6 can have a desired temperature distribution.

After reaching 1300° C., the temperature of the semiconductor substrate 6 is carefully adjusted to a temperature around 1300° C. by the lower heater 8. At this time, the temperature of the semiconductor substrate 6 is measured by a radiation thermometer (not shown) attached to the film-forming apparatus. Then, after it is confirmed that the temperature of the semiconductor substrate 6 measured by the radiation thermometer has reached a predetermined temperature, the number of revolutions of the semiconductor substrate 6 is gradually increased.

Then, the reaction gas 26 is supplied from the reaction gas supply portion 14 and is allowed to flow downward through the shower plate 20 toward the surface of the semiconductor substrate 6 placed inside the body part 30 of the liner 2. At this time, the reaction gas 26 is straightened when passing through the through holes 21 of the shower plate 20 functioning as a straightening vane, and flows downward substantially vertically toward the semiconductor substrate 6 placed under the shower plate 20. That is, the reaction gas 26 forms a so-called vertical flow. Then, when reaching the surface of the heated semiconductor substrate 6, the reaction gas 26 causes a reaction so that an AlN epitaxial film is formed on the surface of the semiconductor substrate 6.

When the thickness of the AlN epitaxial film reaches a predetermined value, the supply of the reaction gas 26 is stopped. At this time, the supply of hydrogen gas as a carrier gas may be continued. In this case, the supply of hydrogen gas may be stopped after it is confirmed that the temperature of the semiconductor substrate 6 measured by the radiation thermometer (not shown) has become lower than a predetermined temperature.

After it is confirmed that the semiconductor substrate has been cooled to a predetermined temperature, the semiconductor substrate 6 is transported out of the chamber 1.

The film-forming apparatus and film-forming method according to the second embodiment have been described above with reference to a case where an AlN epitaxial film is formed. However, the present invention is not limited thereto, and can be applied to, for example, formation of another epitaxial film such as a GaAlN epitaxial film. It is to be noted that the growth temperature of such an AlN or GaAlN epitaxial film as described with reference to the second embodiment is higher than that of a GaN epitaxial film due to Al contained therein. Therefore, the present invention is preferable when such a film is formed. That is, the present invention uniformly heats a substrate to form a film having a predetermined thickness on the substrate.

As described above, the film-forming apparatus according to the present invention is preferably applied to a so-called vertical epitaxial growth apparatus in which a gas required for film formation is supplied from above a wafer placed on a susceptor and a heater is provided on the back surface side of the susceptor.

After the AlN semiconductor layer is formed by the film-forming method according to the second embodiment, a second AlN buffer layer is formed so as to have a thickness of 20 nm. In this way, a group III-V nitride compound semiconductor substrate is produced.

A device layer is formed on the thus obtained semiconductor substrate to produce a semiconductor device. The formation of a device layer will be described with reference to a case where, for example, a PIN junction-type photodiode is formed as a light-receiving element.

On a semiconductor substrate produced using the film-forming apparatus according to the second embodiment, a device layer is formed by stacking a n-type GaAlN layer, an i-type GaAlN layer, a p-type GaAlN superlattice layer, and a p-type GaAlN layer in order.

An n-type GaAlN layer is formed by, for example, the following method. Various raw material gases such as trimethylalminum (Al source), trimethylgallium (Ga source), and ammonia (N source) are used, and SiH₄ (monosilane) gas is allowed to flow as a raw material gas containing N-type impurities. This makes it possible to grow a Si (silicon)-doped n-type GaAlN layer. The thickness of the n-type GaAlN layer is set to a value in the range of between 500 nm to 2000 nm (e.g., 1000 nm).

Then, an i-type GaAlN layer is formed by a MOCVD method so as to have a thickness in the range of between 100 nm to 200 nm (e.g., 200 nm).

Then, a p-type GaAlN superlattice layer is formed on the i-type GaAlN layer. The p-type GaAlN superlattice layer is formed as a multiple quantum well by stacking a 2 nm-thick p-type GaN layer (well layer) and a 3 nm-thick AlN layer (barrier layer) (thickness: 5 nm) in order, and repeating this process 20 times. The p-type GaN layers and the AlN layers constituting the p-type GaAlN superlattice layer are formed by a MOCVD method using the above-mentioned raw material gases as raw materials of GaAlN.

The p-type GaN layer is doped with Mg (magnesium) as p-type impurities by allowing Cp₂Mg (biscyclopentadienylmagnesium) gas to flow as a raw material gas of p-type impurities during the growth of the GaN layer.

Then, a Mg-doped p-type GaAlN layer is grown so as to have a thickness of about 20 nm by a MOCVD method using the above-mentioned raw material gases as raw materials of GaAlN, and Cp₂Mg gas as a raw material gas of p-type impurities. Here, the p-type GaAlN layer is a contact layer whose AlN compositional ratio is reduced to 20% or less to ensure an ohmic contact with a p-type electrode (which will be described later) to satisfactorily perform p-type activation to achieve low resistance. The p-type GaAlN layer may be changed to a p-type GaN layer whose AlN compositional ratio is 0%.

After the device layer is formed in such a manner as described above, the device layer is etched so that part of the n-type GaAlN layer is exposed, and then an n-type electrode is formed in the exposed area and a p-type electrode is further formed on the p-type GaAlN layer. The p-type electrode and the n-type electrode are formed by a well-known method using well-known materials, such as Al, Au, Pd, Ni, and Ti, selected depending on their respective polarities. For example, the p-type electrode is formed by vapor-depositing 10 nm of Pd (palladium) as a first layer and 10 nm of Au (gold) as a second layer and then by forming the layers into a desired planar shape by patterning. The p-type electrode or the n-type electrode may be formed using ZrB₂ as an electrode material.

When the thus obtained semiconductor device is irradiated with external light, the light enters the semiconductor device from the substrate side, passes through the n-type GaAlN layer, and is received and absorbed by the i-type GaAlN layer as a light-receiving region so that photocarriers are generated. Since a predetermined reverse bias electric field is applied between the p-type electrode and the n-type electrode, the generated photocarriers are output to the outside as a photocurrent.

The present invention is not limited to the above-mentioned embodiments and may be utilized without departing from the spirit and scope of the present invention.

According to each of the above embodiments, a substrate is rotated during film formation, but film formation may be performed without rotating a substrate.

Each of the above embodiments has been described with reference to an epitaxial growth apparatus as one example of a film-forming apparatus, but the present invention is not limited thereto. The present invention may be applied to another film-forming apparatus such as a CVD apparatus as long as it is a film-forming apparatus in which a substrate placed in a film-forming chamber is heated while a reaction gas is supplied into the film-forming chamber to form a film on the surface of the substrate.

Obviously many modifications and variations of the present invention are possible in the light of the above teachings. It is therefore to be understood that within the scope of the appended claims the invention may be practiced otherwise than as specifically described.

What is claimed is:

1. A film-forming apparatus comprising:
a film-forming chamber;
a susceptor provided in the film-forming chamber to place a substrate thereon;
a rotating unit that rotates the susceptor;
a heater located below the susceptor; and
a reflector assembly located below the heater,
wherein the reflector assembly is a combination of a ring-shaped reflector and a disk-shaped reflector.

2. A film-forming apparatus according to claim 1, wherein a plurality of ring-shaped reflectors are used.

3. A film-forming apparatus according to claim 1, wherein a plurality of disk-shaped reflectors are used.

4. A film-forming apparatus according to claim 1, wherein the disk-shaped reflector has holes different in diameter thereon.

5. The film-forming apparatus according to claim 1, further comprising an upper heater located above the susceptor.

6. A film-forming apparatus comprising:
a film-forming chamber;
a susceptor provided in the film-forming chamber to place a substrate thereon;
a rotating unit that rotates the susceptor;
a heater located below the susceptor; and
a heat insulator located below the heater,
wherein the heat insulator has an outer circumferential part and an inner circumferential part thinner than the outer circumferential part.

7. The film-forming apparatus according to claim 6, further comprising an upper heater located above the susceptor.

8. A film-forming method comprising:
forming a predetermined film on a substrate in a film-forming chamber while the substrate is heated by a heater provided below the substrate, wherein a reflector assembly, consisting of a ring-shaped reflector and a disk-shaped reflector is provided below the heater.

9. A film-forming method according to claim 8, wherein a plurality of ring-shaped reflectors are used in the film-formation process.

10. A film-forming method according to claim 8, wherein a plurality of disk-shaped reflectors are used in the film-formation process.

11. A film-forming method according to claim 8, wherein the reflector used in the film-formation process is a disk-shaped reflector having holes different in diameter thereon.

12. A film-forming method according to claim 8, wherein a heat insulator is included with the reflector assembly.
